(19) United States
(12) Patent Application Publication
(10) Pub. No.: US 2021/0359168 A1
(43) Pub. Date: Nov. 18, 2021

(54) MICRO LIGHT EMITTING DIODE DISPLAY PANEL AND MANUFACTURING METHOD THEREOF, AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Yongming YIN, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/627,807

(22) PCT Filed: Dec. 24, 2019
(86) PCT No.: PCT/CN2019/127890

§ 371 Date: Dec. 31, 2019

(30) Foreign Application Priority Data
Dec. 12, 2019 (CN) 201911270390.3

(51) Int. Cl. H01L 33/44; H01L 27/15; H01L 33/00; H01L 33/54

(52) U.S. Cl. CPC H01L 33/44; H01L 27/156; H01L 2933/0025; H01L 33/54; H01L 2933/005; H01L 33/005

(57) ABSTRACT

The present invention provides a manufacturing method of a micro light emitting diode display panel. The manufacturing method comprises following steps of: forming an array substrate; forming a patterned photoresist layer on the array substrate, wherein the photoresist layer at least partially exposes the array substrate; coating a solder material layer on the patterned photoresist layer and the array substrate; developing the solder material layer to form a patterned solder material layer; and forming a micro light emitting diode on the solder material layer to form the micro light emitting diode display panel. In the above manner, the present invention can improve a manufacturing accuracy of the patterned solder material layer, and it can be made repeatedly without the need of a steel mesh, which improves a reliability of a process.

### FIELD OF INVENTION

The present invention relates to the field of display technologies, and in particular, to a micro light emitting diode display panel and a manufacturing method thereof, and a display device.

### BACKGROUND OF INVENTION

Micro LEDs (uLEDs) have become a focus of display technology researches in recent years due to their superior display performance, ultra-long life, and low power consumptions.

### Technical Problem

A main manufacturing process of micro LED display screens in the prior art is as follows: First, a TFT substrate is formed. The TFT substrate can be formed by processes like TFT-LCDs or AMOLED displays. After the TFT substrate is formed, a chip soldering material is formed on the substrate. After that, a micro light emitting diode chip is transferred to a pixel specified position by transfer technologies, and the chip is finally soldered and packaged. Throughout the manufacturing process, a solder paste is usually used as a solder material. Based on the chip soldering of the solder paste, the solder paste is usually printed on a stencil to obtain a default pattern. The use of stencil printing makes printing qualities greatly affected by a quality and life of the stencil. As the number of prints increases, characteristics of the stencil will change, which will affect patterning of the solder paste.

### Technical Solution

The present invention provides a micro light emitting diode display panel and a manufacturing method thereof, and a display device, which can solve problems of solder paste patterning in the prior art are affected by quality, life and, characteristics of stencils.

In order to solve the above technical problems, a technical solution adopted in the present invention is to provide a manufacturing method of a micro light emitting diode display panel. The manufacturing method comprises following steps of: forming an array substrate; forming a patterned photoresist layer on the array substrate, wherein the photoresist layer at least partially exposes the array substrate; coating a solder material layer on the patterned photoresist layer and the array substrate; developing the solder material layer to form a patterned solder material layer; and forming a micro light emitting diode on the solder material layer to form the micro light emitting diode display panel.

Wherein, the step of forming the patterned photoresist layer on the array substrate comprises: coating a photoresist material on the array substrate; providing a mask, and aligning the mask and the array substrate; and exposing and developing the array substrate to form the patterned photoresist layer.

Wherein, the mask is one of a negative photoresist or a positive photoresist.

Wherein, the mask comprises at least a fully transparent region and a translucent region.

Wherein, the mask comprises at least an opaque region and a translucent region.

Wherein, a transmittance of the translucent region of the mask ranges from 10% to 90%.

Wherein, the step of forming the micro light emitting diode on the solder material layer to form the micro light emitting diode display panel comprises: transferring the micro light emitting diode to the patterned solder material layer; performing a reflow soldering process on the micro light emitting diode; and encapsulating the micro light emitting diode after the reflow soldering process.

Wherein, the soldering material is solder paste.

In order to solve the above technical problems, another technical solution adopted in the present invention is: Providing a micro light emitting diode display panel according to any one of the above manufacturing methods. The micro light emitting diode display panel comprises: an array substrate; a patterned photoresist layer formed on the array substrate, wherein the photoresist layer at least partially exposes the array substrate; a solder material layer formed on a region of the array substrate that is not covered by the photoresist layer; a light emitting layer comprising a plurality of micro light emitting diodes formed on the solder material layer; and an encapsulation layer covering the photoresist layer and the plurality of the micro light emitting diodes.

In order to solve the above technical problems, the other technical solution used in the present invention is: Providing a display device, wherein the display device comprises the micro light emitting diode display panel as mentioned above.

### BENEFICIAL EFFECT

The beneficial effects of the present invention are: A micro light emitting diode display panel and a manufacturing method thereof, and a display device are provided. A patterned photoresist layer is formed by using a photoresist material in combination with a traditional photolithography process, and a patterned solder material layer is formed instead of a traditional stencil printing for forming a patterned solder material layer. The patterned solder material layer is produced with higher accuracy, and can be made repeatedly without the need of the stencil, which improves a reliability of a process.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a schematic flowchart of a manufacturing method of a micro light emitting diode display panel according to an embodiment of the present invention.

FIG. 2 is a schematic view of manufacturing the micro light emitting diode display panel according to the embodiment of the present invention.

FIG. 3 is a schematic flowchart of step S200 according to the embodiment of the present invention.

FIG. 4 is a schematic structural view of a mask according to the embodiment of the present invention.

FIG. 5 is a schematic flowchart of step S500 according to the embodiment of the present invention.

FIG. 6 is a schematic structural view of the micro light emitting diode display panel according to the embodiment of the present invention.

FIG. 7 is a schematic structural view of a display device according to the embodiment of the present invention.

### DETAILED DESCRIPTION OF PREFERRED EMBODIMENTS

The technical solutions in the embodiments of the present application will be clearly and completely described below with reference to the drawings in the embodiments of the present application, and it is obvious that the described embodiments are only a part of the embodiments of the present application, and not all of the embodiments. All other embodiments obtained by a person of ordinary skill in the art without any inventive work based on the embodiments in the present application are within the scope of protection of the present application.

Unless defined otherwise, all technical and scientific terms used herein have the same meaning as commonly understood by one of ordinary skill in the art to which this application belongs; the terminology used in the description of the application herein is for the purpose of describing particular embodiments only and is not intended to be limiting of the application; the terms “including” and “having,” and any variations thereof, in the description and claims of this application and the description of the above figures are intended to cover non-exclusive inclusions. The terms “first,” “second,” and the like in the description and claims of the present application or in the above-described drawings are used for distinguishing between different objects and not for describing a particular order.

Reference herein to “embodiment” means that a particular feature, structure, or characteristic described in connection with the embodiment can be included in at least one embodiment of the application. The appearances of the phrase in various places in the specification are not necessarily all referring to the same embodiment, nor are separate or alternative embodiments mutually exclusive of other embodiments. It is explicitly and implicitly understood by one skilled in the art that the embodiments described herein can be combined with other embodiments.

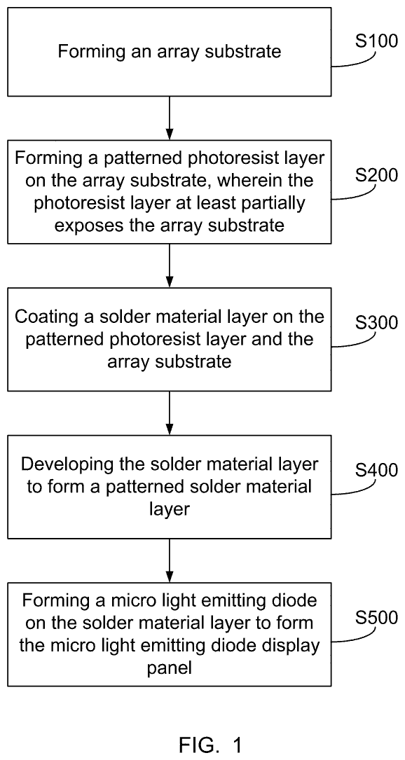

Please refer to FIG. 1. FIG. 1 is a schematic flowchart of a manufacturing method of a micro light emitting diode display panel according to an embodiment of the present invention. As shown in the figure, the manufacturing method of the micro light emitting diode display panel provided by the present invention comprises following steps of:

S100: forming an array substrate.

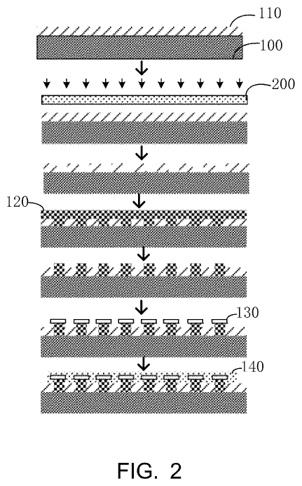

With reference to FIG. 2, FIG. 2 is a schematic view of manufacturing the micro light emitting diode display panel according to the embodiment of the present invention. As shown in FIG. 2, an array substrate 100 is first formed. Optionally, the array substrate 100 may comprise at least a base substrate (not shown), and further comprises a gate layer (not shown), an insulating layer (not shown), a semiconductor layer (not shown), and a pixel electrode (not shown) which are sequentially formed on the base substrate by using the prior art. A source electrode and a drain electrode (not shown) are formed on the semiconductor layer, wherein the drain electrode and the pixel electrode are connected to each other.

Of course, the array substrate 100 provided in the present invention may also comprise other film layer structures in the prior art, which will not be further described here.

S200: forming a patterned photoresist layer on the array substrate, wherein the photoresist layer at least partially exposes the array substrate.

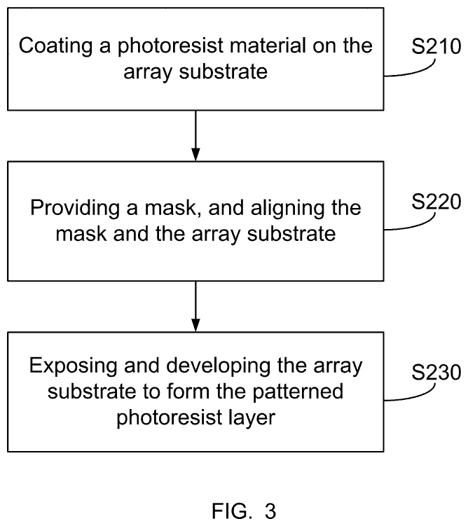

Please further combine FIG. 3, which is a schematic flowchart of step S200 according to the embodiment of the present invention. As shown in FIG. 3, step S200 of the present invention further comprises following sub-steps:

S210: coating a photoresist material on the array substrate.

Further, a photoresist material 110 is coated on the formed array substrate 100. Optionally, the photoresist material 110 in the present invention may be one of a positive photoresist material or a negative photoresist material, which is not specifically limited herein.

S220: providing a mask, and aligning the mask and the array substrate.

A mask 200 is provided in order to ensure the subsequent normal work of the display panel, and the mask 200 and the array substrate 100 can be accurately aligned. That is, to ensure an accurate alignment of patterns on the mask 200.

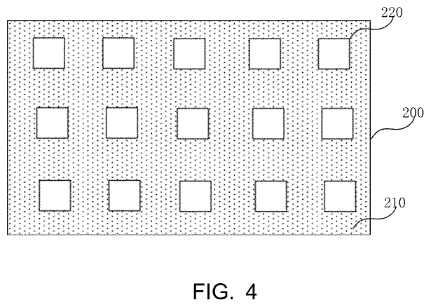

Optionally, in combination with FIG. 4, FIG. 4 is a schematic structural view of the mask according to the embodiment of the present invention. A material of the mask 200 selected in the present invention is one of a positive photoresist material or a negative photoresist material. In a specific application scenario of the present invention, the mask 200 is made of a negative photoresist material, and the mask 200 comprises at least a fully transparent region 210 and a translucent region 220 arranged in an array. A transmittance of the fully transparent region 210 is 100%, and a transmittance of the translucent region 220 ranges from 10% to 90%, which may specifically be 10%, 50%, 90%, etc., and is not specifically limited here.

Of course, in another embodiment of the present invention, the mask 200 may also be made of a positive photoresist material, and the mask 200 comprises at least an opaque region and a translucent region arranged in an array. A transmittance range of the translucent region is the same as when using a negative photoresist material layer, which is 10% to 90%, and can be 10%, 50%, 90%, etc., and is not specifically limited here.

It can be understood that the fully transparent region or the opaque region of the mask 200 in the present invention corresponds to a subsequent position where the solder material is to be applied. That is, a position of the array substrate 100 where the solder material is needed. Then, a corresponding portion of the mask 200 is set as the fully transparent region or the opaque region, thereby ensuring subsequent patterning of the solder material layer.

S230: exposing and developing the array substrate to form the patterned photoresist layer.

Further, the array substrate 100 coated with the photoresist material 110 is first transferred to an exposure machine for an exposure process, thereby transferring the patterns on the mask 200 to the photoresist material 100.

Next, the patterns on the mask 200 are copied onto the photoresist material 110 through a development process, thereby forming the patterned photoresist layer 110. The photoresist layer 110 at least partially exposes the array substrate 100. Specifically, by controlling a development time, a portion where the solder material is not needed is covered by the photoresist layer 110, and a portion where the solder material is needed is developed.

S300: coating a solder material layer on the patterned photoresist layer and the array substrate.

Further, a solder material layer 120 is coated on the patterned photoresist layer 110 and the array substrate 100. The solder material used in the present invention may be a solder paste. Of course, other solder materials may be used in other embodiments, which is not specifically limited here.

S400: developing the solder material layer to form a patterned solder material layer.

Further to FIG. 2, a second development process is performed on the array substrate 100 coated with the solder material layer 120 to form a patterned solder material layer. Specifically, the photoresist layer 110 that was not fully developed during the first development process and the solder material layer covering the undeveloped photoresist layer 110 are developed together to obtain the patterned solder material layer 120.

It can be understood that, in the embodiment of the present invention, the photoresist material is combined with a conventional photolithography process, and the patterned photoresist layer is formed based on a specially designed mask. In the later stage, the solder material layer (i.e. the solder paste) is applied to form the patterned solder material layer to replace a patterned solder material layer formed by a traditional stencil printing. It can obtain more accurate solder paste patterns, and it can be made repeatedly without the need of the stencil, which improves the reliability of the process.

S500: forming a micro light emitting diode on the solder material layer to form the micro light emitting diode display panel.

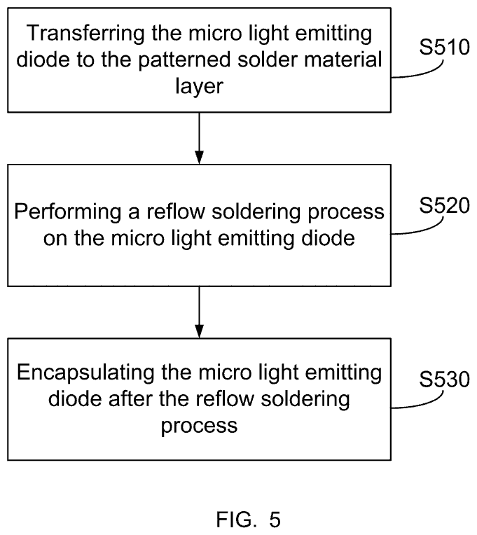

With reference to FIG. 5, FIG. 5 is a schematic flowchart of step S500 according to the embodiment of the present invention. As shown in FIG. 5, step S500 of the present invention further comprises following sub-steps:

S510: transferring the micro light emitting diode to the patterned solder material layer.

A micro light emitting diode 130 is further transferred to the solder material layer 120. It can be understood that a transfer method of the micro light emitting diode in the present invention can refer to the prior art, which is not specifically limited here.

S520: performing a reflow soldering process on the micro light emitting diode.

Further, a reflow soldering process is performed on the micro light emitting diode, so that the micro light emitting diode and PCB pads are reliably combined through the solder material layer 120 (i.e. the solder paste). Specifically, one of vapor phase reflow soldering, infrared reflow soldering, far infrared reflow soldering, infrared heating air reflow soldering, and full hot air reflow soldering may be used, which is not specifically limited here.

S530: encapsulating the micro light emitting diode after the reflow soldering process.

Specifically, an encapsulation layer 140 is formed on the micro light emitting diode 130. The encapsulation layer 140 functions to protect the micro light emitting diode 130 from water vapor intrusion. In addition, in the present invention, the encapsulation layer 140 needs to have good heat resistance, insulation, and film-forming stability. Materials that can be used include, but are not limited to, parylene or organic resin. Optionally, in the present invention, the encapsulation layer 140 may be formed by a spin coating process, and a thickness may be between 50 nm to 0.5 mm.

In the above embodiment, the patterned photoresist layer is formed by using the photoresist material in combination with a traditional photolithography process, and the patterned solder material layer is formed instead of a traditional stencil printing for forming the patterned solder material layer. The patterned solder material layer is produced with higher accuracy, and can be made repeatedly without the need of the stencil, which improves the reliability of the process.

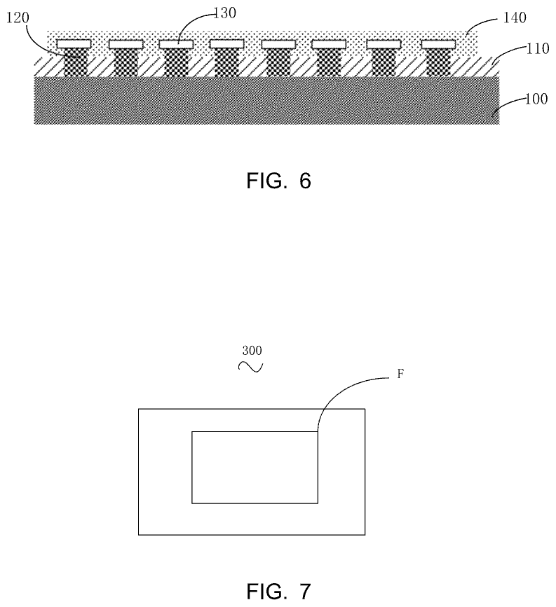

Please refer to FIG. 6. FIG. 6 is a schematic structural view of the micro light emitting diode display panel according to the embodiment of the present invention. As shown in FIG. 6, the present invention provides a micro light emitting diode display panel comprising an array substrate 100, a patterned photoresist layer 110, a solder material layer 120, a light emitting layer (not shown), and an encapsulation layer 140.

The solder material layer 120 is formed on a region of the array substrate 100 that is not covered by the photoresist layer 110.

The light emitting layer comprises a plurality of micro light emitting diodes 130 formed on the solder material layer 120.

The encapsulation layer 140 covers the photoresist layer 110 and the plurality of the micro light emitting diodes 130, and is used to protect the micro light emitting diodes 130 from water vapor intrusion.

It can be understood that the specific manufacturing process of the above micro light emitting diode display panel is detailed in the detailed description of the manufacturing method of the micro light emitting diode display panel of the present invention, and is not repeated here.

Please refer to FIG. 7, which is a schematic structural view of a display device according to the embodiment of the present invention. The display device 300 provided in this application comprises a micro light emitting diode display panel F, and the specific structure and manufacturing process of the micro light emitting diode display panel F are detailed in the specific description of the mentioned embodiments, and are not repeated here.

In summary, those skilled in the art can easily understand that the present invention provides the micro light emitting diode display panel and the manufacturing method thereof, and the display device. The patterned photoresist layer is formed by using the photoresist material in combination with the traditional photolithography process, and the patterned solder material layer is formed instead of the traditional stencil printing for forming patterned solder material layer. The patterned solder material layer is produced with higher accuracy, and can be made repeatedly without the need of the stencil, which improves the reliability of the process.

The above description is only for the purpose of illustrating embodiments of the present application and is not intended to limit the scope of the present application, and all modifications that can be made by the use of the principles of the present application and the accompanying drawings, or directly or indirectly applied to other related technologies are intended to be covered by the scope of the present application.

What is claimed is:

1. A manufacturing method of a micro light emitting diode display panel, comprising following steps of:
forming an array substrate;
forming a patterned photoresist layer on the array substrate, wherein the photoresist layer at least partially exposes the array substrate;
coating a solder material layer on the patterned photoresist layer and the array substrate;
developing the solder material layer to form a patterned solder material layer; and
forming a micro light emitting diode on the solder material layer to form the micro light emitting diode display panel.

2. The manufacturing method as claimed in claim 1, wherein the step of forming the patterned photoresist layer on the array substrate comprises:
coating a photoresist material on the array substrate;
providing a mask, and aligning the mask and the array substrate; and
exposing and developing the array substrate to form the patterned photoresist layer.

3. The manufacturing method as claimed in claim 2, wherein the mask is one of a negative photoresist or a positive photoresist.

4. The manufacturing method as claimed in claim 3, wherein the mask comprises at least a fully transparent region and a translucent region.

5. The manufacturing method as claimed in claim 3, wherein the mask comprises at least an opaque region and a translucent region.

6. The manufacturing method as claimed in claim 4, wherein a transmittance of the translucent region of the mask ranges from 10% to 90%.

7. The manufacturing method as claimed in claim 5, wherein a transmittance of the translucent region of the mask ranges from 10% to 90%.

8. The manufacturing method as claimed in claim 1, wherein the step of forming the micro light emitting diode on the solder material layer to form the micro light emitting diode display panel comprises:
transferring the micro light emitting diode to the patterned solder material layer;
performing a reflow soldering process on the micro light emitting diode; and
encapsulating the micro light emitting diode after the reflow soldering process.

9. The manufacturing method as claimed in claim 1, wherein the soldering material is solder paste.

10. A micro light emitting diode display panel, comprising:
an array substrate;
a patterned photoresist layer formed on the array substrate, wherein the photoresist layer at least partially exposes the array substrate;
a solder material layer formed on a region of the array substrate that is not covered by the photoresist layer;
a light emitting layer comprising a plurality of micro light emitting diodes formed on the solder material layer; and
an encapsulation layer covering the photoresist layer and the plurality of the micro light emitting diodes.

11. A display device, comprising:
a micro light emitting diode display panel, wherein the micro light emitting diode display panel comprises:
an array substrate;
a patterned photoresist layer formed on the array substrate, wherein the photoresist layer at least partially exposes the array substrate;
a solder material layer formed on a region of the array substrate that is not covered by the photoresist layer;
a light emitting layer comprising a plurality of micro light emitting diodes formed on the solder material layer; and
an encapsulation layer covering the photoresist layer and the plurality of the micro light emitting diodes.
